(19) United States
(12) Patent Application Publication
(10) Pub. No.: US 2010/0236614 A1
(43) Pub. Date: Sep. 23, 2010

(54) HYBRID PHOTOVOLTAICS BASED ON SEMICONDUCTOR NANOCRYSTALS AND AMORPHOUS SILICON

(75) Inventors: Victor I. Klimov, Los Alamos, NM (US); Alp T. Findikoglu, Santa Fe, NM (US); Baoquan Sun, Jiangsu (CN); Donald J. Werder, Los Alamos, NM (US); Milan Sykora, Los Alamos, NM (US)

Correspondence Address: LOS ALAMOS NATIONAL SECURITY, LLC, LOS ALAMOS NATIONAL LABORATORY, PPO. BOX 1663, LC/IP, MS A187, LOS ALAMOS, NM, 87545, US

(73) Assignee: LOS ALAMOS NATIONAL SECURITY, LLC, Los Alamos, NM (US)

(21) Appl. No.: 12/701,396

(22) Filed: Feb. 5, 2010

Related U.S. Application Data
(60) Provisional application No. 61/207,012, filed on Feb. 6, 2009.

(51) Int. Cl. H01L 31/00; H01B 1/04

(52) U.S. Cl. 136/255; 136/258; 252/500; 977/773

(57) ABSTRACT

Semiconductor nanocrystals (NCs) are promising materials for applications in photovoltaic (PV) structures that could benefit from size-controlled tunability of absorption spectra, the ease of realization of various tandem architectures, and perhaps, increased conversion efficiency in the ultraviolet through carrier multiplication. The first practical step toward utilization of the unique properties of NCs in PV technologies could be through their integration into traditional silicon-based solar cells. Here, we demonstrate an example of such hybrid PV structures that combine colloidal NCs with amorphous silicon. In these structures, NCs and silicon are electronically coupled, and the regime of this coupling can be tuned by altering the alignment of NC states with regard to silicon band edges. For example, using wide-gap CdSe NCs we demonstrate a photoresponse which is exclusively due to the NCs. On the other hand, in devices comprising narrow-gap PbS NCs, both the NCs and silicon contribute to photocurrent, which results in PV response extending from the visible to the near-infrared. This work demonstrates the feasibility of hybrid PV devices that combine advantages of mature silicon fabrication technologies with the unique electronic properties of semiconductor NCs.

### RELATED APPLICATIONS

This application claims the priority of U.S. Provisional Patent Application 61/207,012, entitled “Hybrid Photovoltaics Based on Semiconductor Nanocrystals and Amorphous Silicon,” which was filed on Feb. 6, 2009, incorporated by reference herein.

### STATEMENT OF FEDERAL RIGHTS

The United States government has rights in this invention pursuant to Contract No. DE-AC52-06NA25396 between the United States Department of Energy and Los Alamos National Security, LLC for the operation of Los Alamos National Laboratory.

### FIELD OF THE INVENTION

The present invention relates to hybrid photovoltaic structures including both a semiconductor nanocrysal layer and a layer of an amorphous silicon.

### BACKGROUND OF THE INVENTION

Semiconductor nanocrystals (NCs) are promising materials for the realization of low-cost, high-efficiency photovoltaics (PV). They can be synthesized and processed via solution-based techniques readily applicable to the fabrication of large-area devices including solar cells. NCs also exhibit a number of unique physical properties that can benefit PV applications. For example, the NC-size-controlled energy gap can be used to tailor the absorption spectrum for the best match to the solar radiation spectrum. Further, one can boost power conversion efficiency via NC-specific processes such as generation of multiple charges by single photons (carrier multiplication) and/or hot-electron extraction in the presence of a “phonon bottleneck.”

A significant challenge in practical applications of NCs in devices such as PV cells and light-emitting diodes (LEDs) is the development of methods for efficient charge extraction/injection and carrier transport. Most of the reported NC-based PV cells and LEDs utilize blends or multilayers of organic molecules (often conducting polymers) and NCs, wherein charge carriers are delivered to or from the electrodes through percolated networks formed by the NCs and the organic molecules. Such structures, however, suffer from low carrier mobilities and poor environmental and photo-stability, primarily because of the involvement of the organic component. To mitigate these problems, Mueller et al. in Nano Lett. 2005, 5, 1039, applied a hybrid LED architecture, in which colloidal NCs were encapsulated in a p-n junction formed by inorganic GaN injection layers. This strategy took advantage of well-established GaN thin-film growth techniques and allowed for efficient injection of electrical charges into NCs with the added benefit of greatly improved stability of the devices.

### SUMMARY OF THE INVENTION

In accordance with the purposes of the present invention, as embodied and broadly described herein, the present invention is directed to a photovoltaic cell including a substrate; a transparent or semi-transparent conductive material layer as a first electrode upon the substrate; a layer of semiconductor nanocrystals upon the transparent or semi-transparent conductive material layer; a layer of amorphous-silicon upon the layer of semiconductor nanocrystals; and, a layer of a metal as a second electrode upon the layer of amorphous silicon.

In another embodiment, the present invention is directed to a photovoltaic cell including a substrate; a transparent or semi-transparent conductive material layer as a first electrode upon the substrate; a layer of semiconductor nanocrystals upon the transparent or semi-transparent conductive material layer; a semiconductor layer of a material selected from the group consisting of amorphous silicon, crystalline silicon, polycrystalline silicon, amorphous germanium, crystalline germanium, polycrystalline germanium, amorphous silicon-germanium alloy, crystalline silicon-germanium alloy or polycrystalline silicon-germanium alloy upon the layer of semiconductor nanocrystals; and, a layer of a metal as a second electrode upon semiconductor layer.

### BRIEF DESCRIPTION OF THE DRAWINGS

FIG. 1 shows hybrid a-Si/CdSe NC PV structures: TEM and spectroscopic characterization. (a) A schematic representation of a cross-sectional structure (left) and a top view (right) of the PV device. (b) A cross-sectional TEM image of the PV structure. (c) and (d) High-resolution TEM images of the ITO/NC and the NC/a-Si interfaces, respectively. (e) The absorption spectra (in terms of optical density, OD) of the NC and a-Si films separately deposited on glass slides. (f) The absorption spectrum of the hybrid a-Si/NC structure.

FIG. 2 shows the effect of NC size on the PV performance of a-Si/NC structures (a-Si was deposited by e-beam evaporation). (a) The size-dependent energies of the NC 1S electron and hole levels (blue lines) plotted as a function of the NC energy gap in comparison to the band-edge positions of a-Si (grey lines); all energies are measured versus vacuum. E_{g,c} is the critical NC gap; sufficiently small NCs with E_{g}>E_{g,c} can inject a photoexcited electron into a-Si. (b) Schematics of energy structures in a PV device operating under short-circuit conditions; the horizontal arrow shows the direction of the internal electric field, E. In this diagram, we only show the flow of charges generated in NCs. Charges generated in the silicon layer do not contribute to photocurrent because holes in a-Si are separated from ITO by a large potential barrier. Holes accumulated at the NC/a-Si interface can, in principle, recombine with electrons photogenerated in NCs. This process, however, is not expected to diminish photocurrent, because the electrons removed by interface recombination are effectively substituted by the electrons photogenerated in silicon. (c) The EQE spectrum (solid red line) of the PV device fabricated using NCs with E_{g}=2.5 eV in comparison to the NC absorption spectrum measured in terms of percentage of absorbed photons (dashed black line); the incident light intensity is approximately 3 mW cm⁻² (similar intensities were utilized in all photocurrent measurements reported here). Inset: The spectral dependence of the photocurrent (solid red line). This plot also shows the dark current (black circles) measured concurrently by blocking incident light. (d) Comparison of PV performance (in terms of EQE on a log scale) of the devices fabricated using NCs with E_{g}=2.5 eV (solid red line) and 2.1 eV (dashed black line).

FIG. 3 shows optimization of the PV performance of a-Si/NC structures. (a) The EQEs of three devices with the same thickness of the a-Si layer (50 nm) and two different thicknesses of the NC layer (150 and 90 nm) fabricated using either e-beam silicon deposition (two lower traces) or magnetron sputtering (upper trace). An adjustment of the NC layer thickness allows for seven-fold enhancement of the EQE (at the 1S peak). An additional seven-fold increase is obtained using magnetron sputtering instead of e-beam deposition for fabricating the a-Si film. This increase results from improved conductivity of the silicon layer as illustrated in the inset, which shows the in-plane photocurrent measured as a function of voltage for a-Si and NC films illuminated by unfiltered light from a xenon source with intensity 46 mW cm⁻². These measurements were conducted on 50 nm thick films deposited on glass slides with two 1.5-mm-long aluminum electrodes separated by the 0.115-mm gap. (b) The comparison of spectrally resolved IQEs for devices fabricated with and without PEDOT:PSS layer on top of the ITO contact. (c) The I-V characteristic of the devices comprising the PEDOT:PSS intermediate layer in dark (dashed black line) and under illumination (solid red line) (same illumination source as in the inset in panel ‘a’).

FIG. 4 shows hybrid a-Si/PbS NC PV structures: Schematics and characterization of PV performance (a-Si was deposited by rf sputtering). (a) An approximate diagram of energy states (shown vs. vacuum) in a PbS NC/a-Si device under the open circuit condition; filling of defect states at the NC/a-Si interface may lead to band bending (not shown) due to formation of a Schottky junction. (b) Comparison of the EQE spectrum of the hybrid PV structure comprising PbS NCs (solid red line) with the absorption spectrum of the NCs (dashed blue line); the NC lowest absorption peak is at 1100 nm. Inset: Comparison of the normalized EQE spectra of the hybrid a-Si/NC device (solid red line) and the all-NC PV structure made without the a-Si layer (dashed black line). (c) In-plane photocurrent as a function of applied bias for films of PbS NCs (100 nm thickness) capped with either OA (dashed gray line) or EDT (dashed-dotted red line) in comparison to that for a film of a-Si (50 nm thickness) fabricated using rf-sputtering (solid blue line); films were illuminated by unfiltered light from a xenon lamp with intensity 36.5 mW cm⁻². These measurements were conducted by applying bias between two 1.5-mm-long Al electrodes separated by the 0.115-mm gap. (d) The I-V characteristic of the devices comprising PbS NCs and a-Si (layer thicknesses are 200 nm and 50 nm, respectively) in dark (dashed gray line) and under illumination (solid red line) (same illumination source as in the inset in panel ‘c’).

### DETAILED DESCRIPTION OF THE INVENTION

In this work, we explore a similar strategy—integration of NCs into traditional thin-film structures—but in application to PV devices. At present, the PV market is dominated by crystalline silicon (c-Si) cells. However, cost considerations have lead to rapid expansion of the PV market segment utilizing amorphous silicon (a-Si). In addition to reduced fabrication cost, a-Si provides the advantage of increased light absorptivity, which allows one to reduce the thickness of a solar cell, and hence material consumption, and the device weight. The efficiencies of a-Si solar cells are still lower than those of devices made of c-Si (˜9% versus ˜25%). Inclusion of NCs can potentially enhance the performance of a-Si PV structures through added flexibility in tailoring the device absorption spectrum, application of tandem architectures, and perhaps, increased conversion efficiency in the ultraviolet through carrier multiplication. From the fabrication prospective, integration of NCs into a-Si devices is facilitated by the fact that amorphous silicon can be grown using low-temperature techniques that are gentle enough to preserve the integrity of colloidal NCs.

As used herein, the term “nanocrystal” refers to particles less than about 150 Angstroms in the largest axis, and preferably from about 10 to about 150 Angstroms. Also, within a particularly selected colloidal nanocrystal, the colloidal nanocrystals are substantially monodisperse, i.e., the particles have substantially identical size and shape.

The nanocrystals are generally colloidal and are members of a crystalline population having a narrow size distribution. The shape of the colloidal nanocrystals can be a sphere, a rod, a disk and the like. In one embodiment, the colloidal nanocrystals include a core of a binary semiconductor material, e.g., a core of the formula MX, where M can be cadmium, zinc, mercury, aluminum, lead, tin, gallium, indium, thallium, magnesium, calcium, strontium, barium, copper, and mixtures or alloys thereof and X is sulfur, selenium, tellurium, nitrogen, phosphorus, arsenic, antimony or mixtures thereof. In another embodiment, the colloidal nanocrystals include a core of a ternary semiconductor material, e.g., a core of the formula M₁M₂X, where M₁ and M₂ can be cadmium, zinc, mercury, aluminum, lead, tin, gallium, indium, thallium, magnesium, calcium, strontium, barium, copper, and mixtures or alloys thereof and X is sulfur, selenium, tellurium, nitrogen, phosphorus, arsenic, antimony or mixtures thereof. In another embodiment, the colloidal nanocrystals include a core of a quaternary semiconductor material, e.g., a core of the formula M₁M₂M₃X, where M₁, M₂ and M₃ can be cadmium, zinc, mercury, aluminum, lead, tin, gallium, indium, thallium, magnesium, calcium, strontium, barium, copper, and mixtures or alloys thereof and X is sulfur, selenium, tellurium, nitrogen, phosphorus, arsenic, antimony or mixtures thereof. In one embodiment, the colloidal nanocrystals are of silicon or germanium. Examples include cadmium sulfide (CdS), cadmium selenide (CdSe), cadmium telluride (CdTe), zinc sulfide (ZnS), zinc selenide (ZnSe), zinc telluride (ZnTe), mercury sulfide (HgS), mercury selenide (HgSe), mercury telluride (HgTe), aluminum nitride (AlN), aluminum sulfide (AlS), aluminum phosphide (AlP), aluminum arsenide (AlAs), aluminum antimonide (AlSb), lead sulfide (PbS), lead selenide (PbSe), lead telluride (PbTe), gallium arsenide (GaAs), gallium nitride (GaN), gallium phosphide (GaP), gallium antimonide (GaSb), indium arsenide (InAs), indium nitride (InN), indium phosphide (InP), indium antimonide (InSb), thallium arsenide (TlAs), thallium nitride (TlN), thallium phosphide (TlP), thallium antimonide (TlSb), zinc cadmium selenide (ZnCdSe), indium gallium nitride (InGaN), indium gallium arsenide (InGaAs), indium gallium phosphide (InGaP), aluminum indium nitride (AlInN), indium aluminum phosphide (InAlP), indium aluminum arsenide (InAlAs), aluminum gallium arsenide (AlGaAs), aluminum gallium phosphide (AlGaP), aluminum indium gallium arsenide (AlInGaAs), aluminum indium gallium nitride (AlInGaN) and the like, mixtures of such materials, or any other semiconductor or similar materials. In another embodiment, the colloidal nanocrystals include a core of a metallic material such as gold (Au), silver (Ag), cobalt (Co), iron (Fe), nickel (Ni), copper (Cu), manganese (Mn), alloys thereof and alloy combinations.

Additionally, the core of any semiconductor material can have an overcoating on the surface of the core. The overcoating can also be a semiconductor material, such an overcoating having a composition different than the composition of the core. The overcoat on the surface of the colloidal nanocrystals can include materials selected from among Group II-VI compounds, Group II-V compounds, Group III-VI compounds, Group III-V compounds, Group IV-VI compounds, Group I-III-VI compounds, Group II-IV-V compounds, and Group II-IV-VI compounds. Examples include cadmium sulfide (CdS), cadmium selenide (CdSe), cadmium telluride (CdTe), zinc sulfide (ZnS), zinc selenide (ZnSe), zinc telluride (ZnTe), mercury sulfide (HgS), mercury selenide (HgSe), mercury telluride (HgTe), aluminum nitride (AlN), aluminum phosphide (AlP), aluminum arsenide (AlAs), aluminum antimonide (AlSb), gallium arsenide (GaAs), gallium nitride (GaN), gallium phosphide (GaP), gallium antimonide (GaSb), indium arsenide (InAs), indium nitride (InN), indium phosphide (InP), indium antimonide (InSb), thallium arsenide (TlAs), thallium nitride (TlN), thallium phosphide (TlP), thallium antimonide (TlSb), lead sulfide (PbS), lead selenide (PbSe), lead telluride (PbTe), zinc cadmium selenide (ZnCdSe), indium gallium nitride (InGaN), indium gallium arsenide (InGaAs), indium gallium phosphide (InGaP), aluminum indium nitride (AlInN), indium aluminum phosphide (InAlP), indium aluminum arsenide (InAlAs), aluminum gallium arsenide (AlGaAs), aluminum gallium phosphide (AlGaP), aluminum indium gallium arsenide (AlInGaAs), aluminum indium gallium nitride (AlInGaN) and the like, mixtures of such materials, or any other semiconductor or similar materials. The overcoating upon the core material can include a single shell or can include multiple shells for selective tuning of the properties. The multiple shells can be of differing materials.

Experimental. In this work, we study devices comprising either wide-gap CdSe NCs or narrow-gap PbS NCs. CdSe NCs capped with trioctylphosphine oxide (TOPO) and trioctylphosphine (TOP) were fabricated using a modified procedure developed by Murray et al., J. AM. Chem. Soc. 1993, 115, 8706. NCs were precipitated from the TOP/TOPO solvent and washed with methanol, and then, dried under an argon flow. Original TOPO/TOP surface ligands were replaced with shorter pyridine molecules. In the ligand-exchange procedure, the NCs were re-dissolved in pyridine (concentration 25 mg/mL) and refluxed under argon for two hours. After cooling the mixture, NCs were precipitated by adding hexane and re-dispersed in anhydrous chloroform/1,2-dicholorobenze with the concentration up to 50 mg/mL. The glass substrates coated with indium tin oxide (ITO) were sequentially washed in water, acetone and isopropanol and then treated by oxygen plasma to remove any residual organic materials. The NCs were spin-coated (1000 rpm) either directly onto ITO electrodes or on top of an intermediate layer of poly(3,4-ethylenedioxythiophene) doped with poly(styrenesulfonate) (PEDOT-PSS); these procedures were performed in a glove box. In order to remove residual solvent and some of the surface-bound pyridine molecules, the films were annealed at 130-160° C. in an argon atmosphere. Exchange of surface ligands and annealing were essential for improving the photoconductivity of the NC films.

Because PbS NCs are extremely prone to degradation upon exposure to oxygen, all work on the fabrication of these NCs and their incorporation into devices was conducted in oxygen-free environment using an argon/nitrogen-purged glove box. All solvents were degassed by purging with argon before their transfer into the glove box. PbS NCs were synthesized according to a modified literature route and purified by precipitation with toluene/ethanol and stored as a powder in dark at −37° C. in a glove-box refrigerator. They were further spun cast from a 50 mg/mL hexane/decane solution onto an ITO-coated glass slide. The NC films were then dipped into the 0.1 M 1,2-ethanedithiol (EDT) acetonitrile solution for several seconds and then dried. This procedure was repeated twice. According to previous studies, the above treatment leads to a significant improvement of carrier transport properties of NC films, which occurs as a result of replacement of original oleic acid (OA) capping molecules (˜2.5 nm length) with shorter EDT ligands (˜0.7 nm length), and possibly, interlinking of the NCs to form a continuous network.

Amorphous Si films were grown at room temperature in a vacuum chamber using either electron-beam (e-beam) evaporation or radio-frequency (rf) magnetron sputtering. For the first method, the growth rate was ˜0.1 nm per second with a chamber background pressure of 1×10⁻⁶ Torr. The film thickness was monitored by a quartz crystal monitor and then verified by a cross-sectional analysis using transmission electron microscopy (TEM). The stray electrons from the source beam were shielded by an aluminum foil to prevent potential damage to the NCs. For magnetron sputtering, argon was used as a carrier gas (4.5 mTorr pressure and 20 sccm flow rate). The sputtering power was 250 W, which provided a growth rate of 0.08 nm per second. To complete the device, aluminum electrodes were evaporated through a shadow mask giving a contact active area of 1-3 mm². In some of the PV structures based on CdSe NCs, the top electrode was also fabricated from gold.

For contacting the fabricated devices, the aluminum and ITO electrodes were bonded with thin copper wires using silver paint. The final device structure was covered with a glass slide and sealed on all sides with a liquid transparent epoxy resin in a glove box. The epoxy was allowed to solidify for 12 hours. During PV characterization, the devices were illuminated from the ITO-electrode side. Optical and PV studies of the fabricated structures were conducted in air under ambient conditions.

For cross-sectional imaging of devices, a focused ion beam (FIB) was utilized to cut a thin slice of the sample. The TEM images were acquired in the bright-field mode using a JEOL 2010 TEM operating at 200 kV.

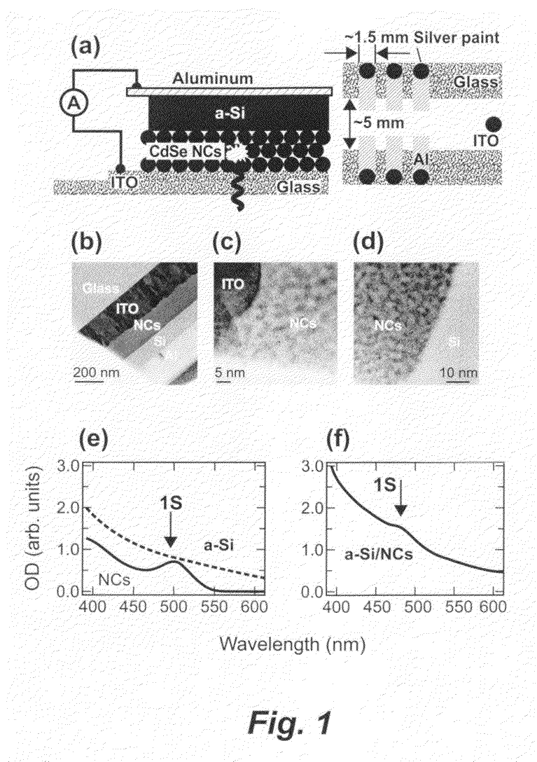

Hybrid a-Si/CdSe NC Structures. A PV structure made of a-Si and CdSe NCs is schematically depicted in FIG. 1a. It comprises a layer (90 to 150 nm thickness) of pyridine-capped CdSe NCs sandwiched between ITO and a-Si layers. Both e-beam evaporation and rf magnetron sputtering allow deposition of a-Si on top of NCs without adversely affecting their physical properties. The thickness of the a-Si layer was typically between 50 and 100 nm. For photocurrent measurements, the structure was completed with an Al electrode.

FIG. 1b shows a cross-sectional transmission electron TEM image of a device comprising a 150 nm thick layer of CdSe NCs and a 100 nm thick silicon film. In this structure, NCs form a dense layer, which is in good physical contact with both Si and ITO, as evident from the higher-resolution images in FIGS. 1c and 1d. Direct deposition of Si onto the NC layer was essential for obtaining electronic coupling at the Si/NC interface. Test structures fabricated by an alternative procedure—spin-coating NCs onto pre-fabricated Si films—did not show any photocurrent.

The higher-resolution TEM images in FIGS. 1c and 1d show resolvable lattice fringes of CdSe NCs, which indicates that the NC integrity is preserved during silicon film growth. The latter is also confirmed by spectroscopic studies. Specifically, optical absorption measurements show that the lowest-energy, 1S absorption feature of the NCs is preserved in the final device structure (compare FIGS. 1e and 1f). Further, NC photoluminescence (not shown), although quenched, is still observable following silicon deposition.

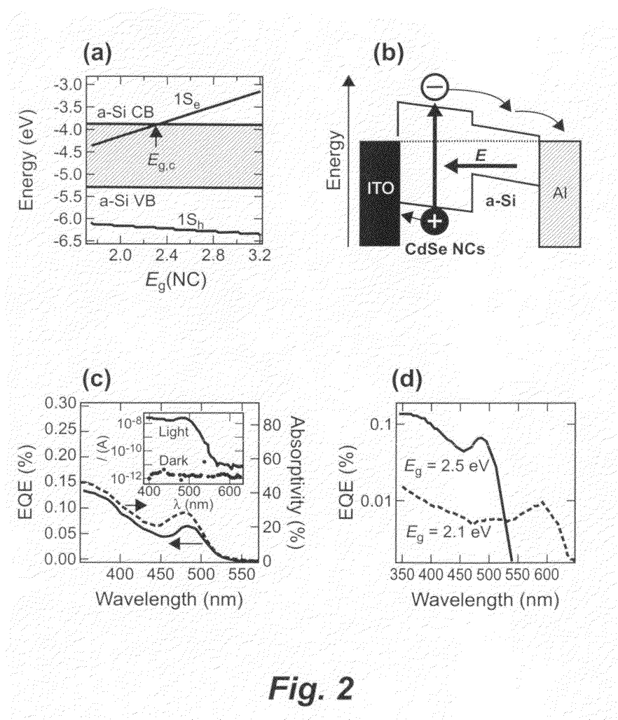

To understand the performance of the fabricated devices, one needs to take into consideration the alignment of CdSe NC electronic states with respect to those of a-Si. In FIG. 2a, we show the energies of the conduction and the valence band edges (denoted CB and VB, respectively) of a-Si together with NC-size-dependent positions of the lowest-energy electron (1Sₑ) and hole (1Sₕ) levels plotted as a function of NC energy gap, E_{g}. The confinement-induced shifts of NC quantized states with respect to bulk-semiconductor band edges (ΔEₑ and ΔEₕ) can be estimated from the following approximate expression: ΔEₑ₍ₕ₎=(E_{g}−E_{g,0)}mₕ₍ₑ₎(mₕ+mₑ)⁻¹, where E_{g,0} is the bulk-semiconductor energy gap, and mₑ and mₕ are the electron and hole effective masses. Because in CdSe electrons are much lighter than holes (mₕ/mₑ≈6), quantum confinement mostly affects the positions of the electron states. In the case of a CdSe—NC/Si interface the tunability range provided by the quantum-size effect is sufficient to shift the 1Sₑ level from below to above the a-Si conduction-band edge (FIG. 2a). The latter should dramatically modify the regime of electronic interactions at the NC/Si interface if NCs and Si are in direct electrical contact. Specifically, NCs of larger sizes with E_{g} below E_{g,c}=2.3 eV should act as acceptors of electrons from the conduction band of Si, while smaller NCs (E_{g}>E_{g,e}) should efficiently inject photogenerated electrons into Si (FIG. 2a).

To study electronic interactions at NC/Si interface, we analyze the PV response of devices fabricated using NCs of two different sizes (energy gaps 2.5 and 2.1 eV) that according to the diagram in FIG. 2a correspond to two different injection regimes. Since these structures are composed of thin layers of undoped materials, we expect that their operation is similar to that of, for example, thin-film polymer PV cells and can be described by the metal-insulator-metal (MIM) model. If such devices are under the short-circuit condition, the Fermi levels in the electrode materials come to equilibrium, which results in the buildup of an internal electric field, E. In the case of ITO and Al, this field provides a driving force that directs electrons toward the Al electrode, while holes are directed to the ITO contact as illustrated in FIG. 2b. Under the open-circuit condition, a difference in electrode's work functions defines an output voltage (V_{oc}).

Given the alignment of the valence-band states at the Si/NC interface and the direction of the internal field, the PV response of the fabricated structures should be exclusively due to the NCs, because holes generated in silicon are blocked from the ITO contact by a large potential barrier. On the other hand, holes generated in the NCs can be efficiently collected by the ITO electrode for all NC sizes. The situation, however, is different for photogenerated electrons. For larger NCs, in which the 1Sₑ level is below the a-Si conduction-band edge, the electrons are blocked from the Al electrode by a potential barrier. On the other hand, NCs of sufficiently small size with E_{g}>E_{g,c} can inject electrons into Si, which should result in a photocurrent.

Experimental data indeed indicate a strong dependence of a photoresponse of the fabricated structures on NC size. For the device that comprises NCs with E_{g}=2.5 eV, the spectrum of external quantum efficiency (EQE) mimics the NC absorption spectrum (FIG. 2c; compare solid red and dashed black lines). The leakage current measured under “dark” conditions is very small, on the order of 1 picoamp per mm² (inset in FIG. 2c), as expected for these structures made of undoped materials. The EQE values are greatly reduced in the device made of the NCs with E_{g}=2.1 eV (compare dashed black and solid red lines in FIG. 2d), because for this NC size, the 1Sₑ level is below the a-Si conduction band edge, which inhibits electron injection into the silicon layer. These results indicate the possibility of obtaining good electronic coupling between NCs and Si, and also demonstrate our ability to control the charge flow at the NC/Si interface through the quantum-size effect. Similar control of interfacial charge transfer was recently demonstrated for CdSe NCs immobilized on the surface of nanocrystalline titania.

We have performed an initial study of devices in which a top contact is fabricated not from aluminum but gold. Since gold has a higher work function than ITO it is expected that the polarity of such devices should be opposite to that of PV cells with an Al electrode. The fabricated structures indeed show reversal in the direction of the photogenerated current. Further, the measured open circuit voltage (˜0.5 V) is consistent with the difference between the work functions of Au and ITO. These results confirm the validity of the MIM model for describing hybrid a-Si/CdSe NC devices.

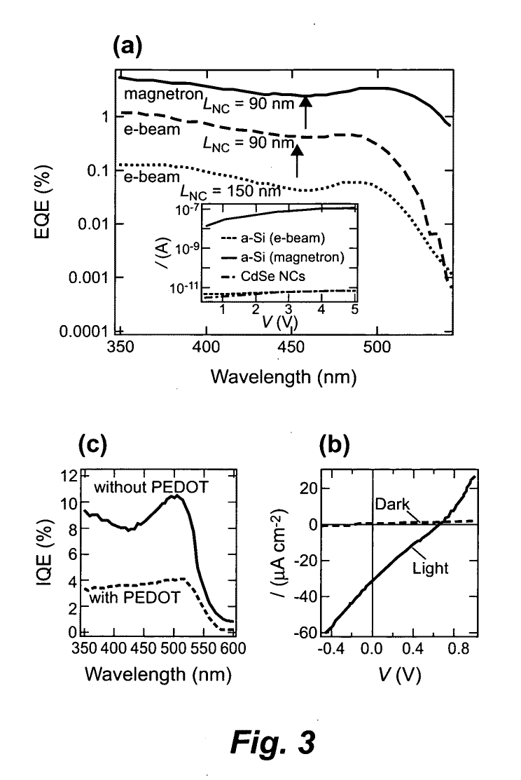

We have conducted a preliminary analysis of the factors that affect performance of our hybrid a-Si/NC structures. Based on the EQE spectra (see, e.g., FIG. 2c), the measured PV response is dominated by light absorption in the NCs. The optimal thickness of an NC layer (L_{NC}), which maximizes EQE, is determined by a compromise between the device absorptivity (increases with increasing L_{NC}) and transport losses (decrease with decreasing L_{NC}). To analyze the effect of L_{NC} on EQE, we have fabricated a series of devices with the same thickness of the silicon layer (L_{Si}=50 nm) but different thicknesses of the NC layer down to 90 nm. The trend observed by us is a gradual increase in EQE with decreasing L_{NC}. For example, for L_{NC}=150 nm, the EQE measured at the position of the 15 feature is ˜0.1% and it increases to 0.5% for the 90 nm structure (FIG. 3a; dotted blue and dashed black lines). Unfortunately, for thinner devices, we could not avoid short-circuiting, which prevented us from reaching the thickness that maximizes EQE by optimizing the relationship between the amount of absorbed light and transport losses. These results clearly indicate that one of the limiting factors in the performance of these devices is low photoconductivity of the NC layer.

Poor transport properties of NC assemblies have always been a serious obstacle in the realization of electronic and optoelectronic applications of NCs. However, over the past several years significant progress has been made with regard to both fundamental understanding of charge transport in NC solids and development of practical methods for its improvement. One such practical approach is the use of shorter ligand molecules, which leads to decreased separation between adjacent NCs and results in increased photoconductivity. Further steps may involve more complete removal of surface capping molecules, “wiring” NCs with bi-functional linking groups, and doping of the NC solids. As discussed below, the use of short, bi-functional linkers allows us to greatly improve conductivity of NC films in the case of devices utilizing PbS nanoparticles.

To analyze the effect of silicon charge transport properties on the PV performance of our devices, we have tested different methods/regimes for a-Si deposition. In these studies, we have observed that the use of rf magnetron sputtering produces a material with much better charge transport properties than those obtained with e-beam evaporation. As indicated by current-voltage (I-V) measurements conducted on illuminated films of a-Si and NCs (inset of FIG. 3a), the photoconductivity of a-Si fabricated by e-beam evaporation is comparable to that of the NC film. Therefore, the performance of hybrid PV structures made by this technique is limited by carrier transport in both the NC and a-Si device components. Silicon films made by magnetron sputtering show a photocurrent that is more than three orders of magnitude higher than that for the NC films. In this case, the main limiting factor in the device performance becomes charge transport in the NC layer.

The improvement in the a-Si conductivity leads to a significant increase in the measured EQE values. For example, the device with L_{NC}=90 nm and L_{Si}=50 nm made by magnetron sputtering shows a 1S EQE of ca. 4%, while a similar structure fabricated by e-beam evaporation has an EQE of only ˜0.5% (FIG. 3a; compare solid red and dashed black lines). Because of the small thickness of these structures, they do not absorb all incident light. Therefore, their internal quantum efficiencies (IQEs) can be much higher than the EQE values. For example for the device with 4% EQE, the 1S IQE is greater than 10% (solid red line in FIG. 3b).

As discussed earlier, in ideal MIM structures, the open circuit voltage is determined by the difference in the electrode work functions, which is in the 0.4-0.6 V range for ITO and Al. In real thin-film devices, however, the measured values can be much lower because of the development of microscopic shorts between electrodes. The likelihood of such shorts is particularly high in the case of the ITO electrodes that are known to exhibit significant surface roughness. This problem is typically mitigated by using an intermediate hole-conducting layer of PEDOT-PSS on top of ITO for reducing roughness.

In our CdSe—NC based devices, the use of the PEDOT-PSS was essential for consistently obtaining a high open-circuit voltage. The devices without this intermediate layer often exhibit very small V_{oc} (<0.1 V). On the other hand, using ITO electrodes coated with PEDOT-PSS, we systematically obtain a high open-circuit voltage of up to 0.66 V (FIG. 3c), in agreement with estimations based on the MIM model. While allowing one to produce a higher output voltage, introduction of PEDOT-PSS leads to some reduction of a short-circuit current (typically by a factor of ˜2) and a corresponding decrease in the EQE and IQE values as illustrated in FIG. 3b.

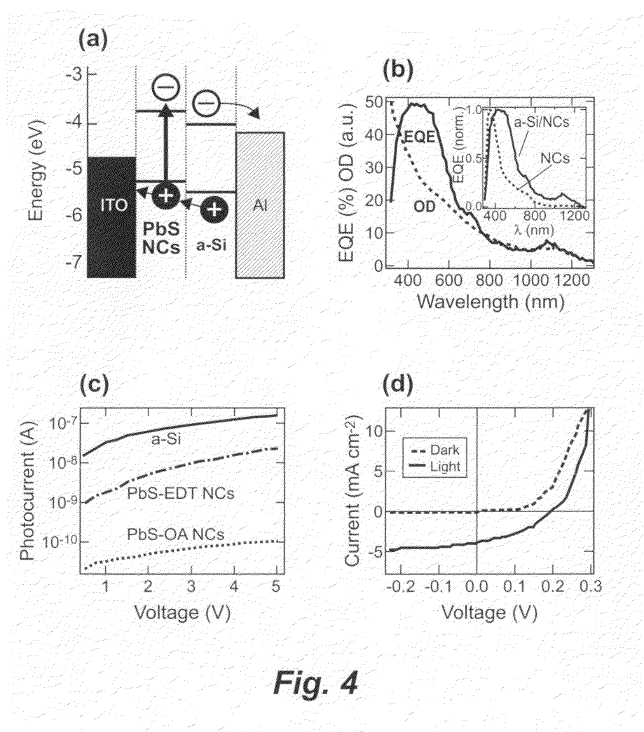

Hybrid a-Si/PbS NC Structures. In the above structures comprising CdSe NCs, the PV response is entirely due to the NCs, while photons absorbed in the a-Si film do not contribute to photocurrent. One might expect that the overall PV performance can be improved using structures, in which PV response is due to charge carriers generated in both the NC and a-Si layers. To realize this type of performance, we combine a-Si deposited via rf-magnetron sputtering with IR absorbing PbS NCs. According to the diagram in FIG. 4a, electrons photogenerated in PbS NCs can be transferred into amorphous silicon and then collected at the Al electrode. Further, the alignment of the valence-band states at the PbS NC/a-Si interface favors hole transfer from silicon into NCs followed by collection at the ITO electrode. Thus, this structure is expected to show photocurrent due to both a-Si and the NCs.

Indeed, the fabricated devices show the expected performance. In FIG. 4b, we compare the EQE spectrum of the PV structure comprising a-Si and PbS NCs (E_{g}=1.13 eV) with the NC absorption spectrum. Because of the small energy gap of the NCs, this structure shows a good PV response in the near-IR down to ˜1200 nm. The EQE at low energies (wavelength, λ>800 nm) mimics the spectral shape of NC absorption, indicating that in this spectral range, the photocurrent is primarily due to the NCs. For wavelengths shorter than ˜800 nm, the EQE shows faster growth with decreasing λ than the NC absorption, which is a signature of contribution from charges generated in the a-Si layer. The fact that in this case, the a-Si layer contributes to the measured photocurrent is also evident from the comparison of the EQE spectra of the hybrid a-Si/NC structures and the devices made just of PbS NCs (see inset in FIG. 4b). Thus, as expected based on the diagram in FIG. 4a, hybrid structures comprising PbS NCs allow one to collect photogenerated carriers from both the NC and the a-Si device components.

The PbS NC-based devices show PV performance, which is considerably improved compared to that of structures comprising CdSe NCs. One factor contributing to this improvement is increased spectral coverage. Specifically, the use of narrow-gap NCs allows us to extend the device operational range into the IR region, and thus, efficiently harvest low-energy photons (for example, for the structure in FIG. 4b, the 1100 nm photons are converted into electrical charges with EQE of ˜7%). Further, these devices also show high quantum efficiencies in the visible (EQE is up to ˜50% and IQE is as high as ˜80% in the green-blue region of the optical spectrum), which is a result of both a steep increase in absorbtivity of PbS NCs at shorter wavelengths and increasing contribution from carriers generated in the a-Si layer.

An additional factor contributing to the enhanced PV performance is improved charge transport properties of PbS NC films compared to films of CdSe NCs. For example, based on the data in the inset of FIG. 3a, photoconductivity of pyridine-treated CdSe NC films is more than 3 orders of magnitude lower than that of a-Si films. In the case of PbS NC films, we observe a similar difference for as-prepared nanoparticles capped with OA ligands (FIG. 4c; compare dashed gray and solid blue lines). However, the replacement of original ligands with shorter, bi-functional molecules of EDT increases the photocurrent by ca. two orders of magnitude (dashed-dotted red line in FIG. 4c). As a result, EDT-treated NC films show photoconductivity, which is only an order of magnitude lower than that of a-Si.

To further characterize our PbS—NC based devices, we study their I-V characteristics in dark (dashed gray line in FIG. 4d) and under white light illumination (unfiltered light from a xenon lamp) at 36.5 mW cm⁻² (solid red line in FIG. 4d). These measurements indicate the open circuit voltage of 0.2 eV, the short-circuit current (I_{sc}) of 4.13 mA cm⁻², and the fill factor of 0.39, which corresponds to a power conversion efficiency of 0.9%. To estimate the device efficiency expected under standard solar illumination (100 mW cm⁻²), we integrate the measured spectral dependence of EQE from FIG. 4b weighted by the AM1.5G solar spectrum from 350 to 1300 nm. This procedure yields a short circuit current of 8.99 mA cm⁻². If we further assume that V_{oc} and the fill factor are the same as those measured at a light intensity of 36.5 mW cm⁻², we obtain an efficiency of 0.7%. This value likely underestimates the actual performance under solar light conditions because the open circuit voltage is expected to increase with increasing intensity of illumination.

We have noticed that I-V characteristics of PbS—NC-based devices transform from diode-like to ohmic (low-resistance resistor) once exposed to air for a few minutes. This result is consistent with the finding of extreme air-sensitivity of PbSe—NC-structures in the report by Luther et al., Nano Lett. 2008, 8, 3488. Interestingly, this rapid degradation in the PV performance is not accompanied by any dramatic changes in optical properties (i.e., absorption spectra).

Based on our experience with cells comprising CdSe NCs, incorporation of an intermediate PEDOT-PSS layer helps to improve V_{oc}. Unfortunately, in the case of PbS—NC devices, we could not use the PEDOT-PSS layer because it was unstable in acetonitrile used in the ligand exchange procedure. However, despite low V_{oc} values, the overall performance of our structures approaches that of the best reported solar cells comprising PbS and PbSe NCs. These literature devices show EQEs in the visible up to 60-70%, V_{oc} of ca. 0.2-0.3 V, and the power conversion efficiency in the ˜1 to ˜2% range.

While operation of cells comprising CdSe NCs can be described in terms of the MIM structure, in is not clear whether this model directly applies to devices made of PbS NCs. Specifically, previous studies indicate that the EDT treatment can lead to effective p-doping of lead-salt NC films. As a result, devices comprising PbS or PbSe NCs sandwiched between two conductors were described in terms of a Schottky junction solar cell. Based on this previous work, our devices also likely comprise a Schottky junction, which is formed at the NC/a-Si interface due to a high density of defect states generated during silicon deposition. The resulting V_{oc} is likely determined by contributions from both a potential drop across the a-Si layer and a built-in potential in a depletion layer of the Schottky junction. One important feature of hybrid NC/a-Si devices demonstrated here is great flexibility in controlling their electronic and optical properties, which can be used to improve PV characteristics such as V_{oc} and I_{sc}. As mentioned above, V_{oc} of solar cells based on NCs of PbS and PbSe is likely defined by the Schottky barrier formed at the metal-electrode. For an ideal Schottky junction, the barrier height is typically limited by (⅔)E_{g}, while it is even lower in real device structures because of pinning of the surface Fermi level by interfacial defects. The latter effect likely explains small V_{oc}, values for devices comprising lead-salt NCs. In principle, the use of a-Si/NC bi-layers can increase V_{oc}, by replacing a poorly controlled Schottky junction with a well defined p-n junction fabricated using chemical doping of lead-salt NCs in combination with traditional methods for a-Si doping. Introduction of a p-n junction into in the PV structure should also help to increase I_{sc} through improvements in charge separation and transport. A further increase in I_{sc} can be obtained through control of parameters such as the thicknesses of the silicon and NC layers together with an NC absorption onset for optimizing the coverage of the solar spectrum. In addition to potential enhancement in the PV performance, encapsulation of NCs into a-Si, which isolates them from environment, could also help improving the stability of devices with regard to oxidation, which is especially important in the case of lead-salt NCs.

Conclusions. We have demonstrated functional PV structures that combine colloidal NCs with amorphous silicon. The PV response of these devices can be controlled by varying energies of electronics states in NCs by either changing the NC size or the composition. As expected based on energy offsets at the a-Si/NC interface, the structures comprising nanoparticles of CdSe show a PV response, which is exclusively due to the NC device component. Further, by changing the NC size, we can control the efficiency of charge transfer across the a-Si/NC interface, and hence, the generated photocurrent. By replacing CdSe NCs with NCs of PbS, we obtain a photoresponse that has contributions from both NCs and a-Si, again in agreement with the alignment of energy states at the a-Si/PbS NC interface. The PbS NC-based devices show a good PV response extended into the near-IR with EQEs of ˜7% at 1100 nm and up to ˜50% in the visible. An encouraging practical aspect of this work is that magnetron sputtering, which is a common industrial fabrication technique, is apparently compatible with colloidal NCs, which could facilitate practical applications of these hybrid PV devices.

### REFERENCES

(1) Greenham, N. C.; Peng, X. G.; Alivisatos, A. P. Phys. Rev. B 1996, 54, 17628.
(2) Nozik, A. J. Physica E 2002, 14, 115.
(3) Huynh, W. U.; Dittmer, J. J.; Alivisatos, A. P. Science 2002, 295, 2425.
(4) Plass, R.; Pelet, S.; Krueger, J.; Graetzel, M.; Bach, U. J. Phys. Chem. B 2002, 106, 7578.
(5) Kamat, P. V. J. Phys. Chem. C 2007, 111, 2834.
(6) Gur, I.; Fromer, N. A.; Geier, M. L.; Alivisatos, A. P. Science 2005, 310, 462.
(7) Koleilat, G.; Levina, L.; Shukla, H.; Myrskog, S. H.; Hinds, S.; Pattantyus-Abraham, A. G.; Sargent, E. H. ACS Nano 2008, 2, 833.
(8) Schaller, R. D.; Klimov, V. I. Phys. Rev. Lett. 2004, 92, 186601.
(9) Ellingson, R.; Beard, M. C.; Johnson, J. C.; Yu, P.; Micic, 0.1.; Nozik, A. J.; Shabaev, A.; Efros, A. L. Nano Lett. 2005, 5, 865.
(10) Colvin, V. L.; Schlamp, M. C.; Alivisatos, A. P. Nature 1994, 370, 354.
(11) Dabbousi, B. O.; Bawendi, M. G.; Onitsuka, O.; Rubner, M. F. Appl. Phys. Lett. 1995, 66, 1316.
(12) Mueller, A. H.; Petruska, M. A.; Achermann, M.; Werder, D. J.; Akhadov, E. A.; Koleske, D. D.; Hoffbauer, M. A.; Klimov, V. I. Nano Lett. 2005, 5, 1039.
(13) Green, M. A. Silicon solar cells: Advanced principles and practice; Bridge Printery: Sydney, 1995.
(14) Green, M. A.; Emery, K.; Hiskawa, Y.; Warta, W. Prog. Photovolt.: Res. Appl. 2007, 15, 425
(15) Murray, C. B.; Norris, D. J.; Bawendi, M. G. J. Am. Chem. Soc. 1993, 115, 8706.
(16) Hines, M. A.; Scholes, G. D. Adv. Mater. 2003, 15, 1844.
(17) Luther, J. M.; Law, M.; Beard, N. C.; Song, Q.; Reese, M. O.; Ellingson, R. J.; Nozik, A. J. Nano Lett. 2008, 8, 3488.
(18) Brus, L. E. J. Chem. Phys. 1983, 79, 5566.
(19) Hoppe, H.; Sariciftci, N. S. J. Mater. Res. 2004, 19, 1924.
(20) Robel, I.; Kuno, M.; Kamat, P. V. J. Am. Chem. Soc. 2007, 129, 4136.
(21) Morgan, N. Y.; Leatherdale, C. A.; Drndic, M.; Jarosz, M. V. K., M. A.; Bawendi, M. G. Phys. Rev. B 2002, 66, 075339/1.
(22) Yu, D.; Wang, C. J.; Wehrenberg, B. L.; Guyot-Sionnest, P. Phys. Rev. Lett. 2004, 92, 216802/1.
(23) Leatherdale, C. A.; Kagan, C. R.; Morgan, N. Y.; Empedocles, S. A.; Kastner, M. A.; Bawendi, M. G. Phys. Rev. B 2000, 62, 2669.
(24) Guyot-Sionnest, P.; Wang, C. J. Phys. Chem. B 2003, 107, 7355.
(25) Yu, D.; Wang, C.; Guyot-Sionnest, P. Science 2003, 300, 1277.
(26) Talapin, D. V.; Murray, C. B. Science 2005, 310, 86.
(27) Granstrom, M.; Petritsch, K.; Arias, A. C.; Lux, A.; Andersson, M. R.; Friend, R. H. Nature 1998, 395, 257.
(28) Johnston, K. W.; Pattantyus-Abraham, A. G.; Clifford, J. P.; Myrskog, S. H.; MacNeil, D. D.; Levina, L.; Sargent, E. H. Appl. Phys. Lett. 2008, 92, 151115.
(29) Sze, S. M. Physics of Semiconductor Devices, Second Edition ed.; John Wiley & Sons: New York, 1981.

In all embodiments of the present invention, all percentages are by weight of the total composition, unless specifically stated otherwise. All ratios are weight ratios, unless specifically stated otherwise. All ranges are inclusive and combinable. The number of significant digits conveys neither a limitation on the indicated amounts nor on the accuracy of the measurements. All numerical amounts are understood to be modified by the word “about” unless otherwise specifically indicated. All documents cited in the Detailed Description of the Invention are, in relevant part, incorporated herein by reference; the citation of any document is not to be construed as an admission that it is prior art with respect to the present invention. To the extent that any meaning or definition of a term in this document conflicts with any meaning or definition of the same term in a document incorporated by reference, the meaning or definition assigned to that term in this document shall govern.

Whereas particular embodiments of the present invention have been illustrated and described, it would be obvious to those skilled in the art that various other changes and modifications can be made without departing from the spirit and scope of the invention. It is therefore intended to cover in the appended claims all such changes and modifications that are within the scope of this invention.

What is claimed is:

1. A photovoltaic cell comprising:
a substrate;
a transparent or semi-transparent conductive material layer as a first electrode upon the substrate;
a layer of semiconductor nanocrystals upon the transparent or semi-transparent conductive material layer;
a layer of amorphous-silicon upon the layer of semiconductor nanocrystals; and,
a layer of a metal as a second electrode upon the layer of amorphous silicon.

2. The photovoltaic cell of claim 1 wherein said cell is formed by:
depositing the transparent or semi-transparent conductive material layer as a first electrode upon the substrate;
depositing the layer of semiconductor nanocrystals upon the transparent or semi-transparent conductive material layer;
depositing the layer of amorphous-silicon upon the layer of semiconductor nanocrystals; and
depositing the layer of a metal as a second electrode upon the layer of amorphous silicon.

3. A photovoltaic cell comprising:
a substrate;
a transparent or semi-transparent conductive material layer as a first electrode upon the substrate;
a layer of semiconductor nanocrystals upon the transparent or semi-transparent conductive material layer;
a semiconductor layer of a material selected from the group consisting of amorphous silicon, crystalline silicon, polycrystalline silicon, amorphous germanium, crystalline germanium, polycrystalline germanium, amorphous silicon-germanium alloy, crystalline silicon-germanium alloy or polycrystalline silicon-germanium alloy upon the layer of semiconductor nanocrystals; and,
a layer of a metal as a second electrode upon semiconductor layer.

4. The photovoltaic cell of claim 1 wherein the semiconductor layer is intrinsic or p- or n-type doped.

5. The photovoltaic cell of claim 3 wherein the semiconductor layer is intrinsic or p- or n-type doped.

6. The photovoltaic cell of claim 1 wherein the semiconductor nanocrystals are selected from the group consisting of M₁X, M₁M₂X, and M₁M₂M₃X, where M₁, M₂, and M₃ are each selected from the group consisting of Zn, Cd, Hg, Al, Ga, In, Tl, Pb, Sn, Mg, Ca, Sr, Ba, mixtures and alloys thereof and X is selected from the group consisting of S, Se, Te, As, Sb, N, P and mixtures thereof, Si, Ge and alloys thereof.

7. The photovoltaic cell of claim 1 wherein the semiconductor nanocrystals are intrinsic or p- or n-type doped.

8. The photovoltaic cell of claim 3 wherein the semiconductor nanocrystals are intrinsic or p- or n-type doped.

9. The photovoltaic cell of claim 1 wherein the transparent conductive oxide is indium-tin oxide (ITO), or other transparent conductive oxides such as zinc-doped indium tin oxide (ZITO), zinc indium oxide (ZIO), gallium indium oxide (GIO), zinc tin oxide (ZTO), fluorine-doped tin oxide (FTO), aluminum-doped zinc oxide (AZO), gallium-doped zinc oxide (GZO), In₄Sn₃O₁₂ and zinc magnesium oxide (Zn₍₁₋ₓ₎MgₓO, where 0.1<x<1).

10. The photovoltaic cell of claim 1 wherein the substrate is glass, quartz, transparent plastic (e.g. optical-grade polyester), or other materials optically transparent in the spectral range 200 to 2000.

11. The photovoltaic cell of claim 1 wherein the semiconductor nanocrystals are selected from the group consisting of cadmium sulfide (CdS), cadmium selenide (CdSe), cadmium telluride (CdTe), zinc sulfide (ZnS), zinc selenide (ZnSe), zinc telluride (ZnTe), mercury sulfide (HgS), mercury selenide (HgSe), mercury telluride (HgTe), aluminum nitride (AIN), aluminum phosphide (AlP), aluminum arsenide (AlAs), aluminum antimonide (AlSb), gallium arsenide (GaAs), gallium nitride (GaN), gallium phosphide (GaP), gallium antimonide (GaSb), indium arsenide (InAs), indium nitride (InN), indium phosphide (InP), indium antimonide (InSb), thallium arsenide (TlAs), thallium nitride (TlN), thallium phosphide (TlP), thallium antimonide (TlSb), lead sulfide (PbS), lead selenide (PbSe), lead telluride (PbTe), and mixtures of such materials

12. The photovoltaic cell of claim 1 wherein the second electrode is a metal selected from the group consisting of aluminum, gold, silver, platinum, copper, and calcium.

13. The photovoltaic cell of claim 1 wherein the layer of semiconductor nanocrystals has a thickness of from about 50 nm to about 10 μm.

14. The photovoltaic cell of claim 1 wherein the layer of amorphous-silicon has a thickness of from about 25 nm to about 10 μm.

15. The photovoltaic cell of claim 1 further including, a layer of a semiconductor material situated between the transparent conductive oxide and the layer of semiconductor nanocrystals.

16. The photovoltaic cell of claim 1 further including a layer of a semiconductor material situated between the transparent conductive oxide and the layer of semiconductor nanocrystals that is fabricated of intrinsic or doped silicon, germanium, or silicon-germanium in either crystalline, polycrystalline or amorphous forms.

17. The photovoltaic cell of claim 1 further including a layer of a hole-conducting material situated between the transparent conductive oxide and the layer of semiconductor nanocrystals.

18. The photovoltaic cell of claim 10 wherein the hole-conducting material is selected from the group consisting of poly(3,4-ethylenedioxythiophene doped with poly(styrene sulphonate) (PEDOT:PSS).

19. The photovoltaic cell of claim 1 wherein the semiconductor nanocrystals are of lead sulfide.

20. The photovoltaic cell of claim 19 characterized by an internal quantum efficiency of about 80 percent and an external quantum efficiency of about 50 percent within the green-blue region of the spectrum.

21. The photovoltaic cell of claim 19 wherein the lead sulfide nanocrystals include a bi-functional ligand as capping molecules.

22. The photovoltaic cell of claim 19 wherein the bi-functional ligand is 1,2-ethanedithiol

23. A composite comprising:
a layer of semiconductor nanocrystals having a layer of amorphous-silicon upon the layer of semiconductor nanocrystals deposited thereon.
